(19) United States
(12) Patent Application Publication
(10) Pub. No.: US 2014/0183545 A1
(43) Pub. Date: Jul. 3, 2014

(54) POLARIZATION EFFECT CARRIER GENERATING DEVICE STRUCTURES HAVING COMPENSATION DOPING TO REDUCE LEAKAGE CURRENT

(71) Applicant: RAYTHEON COMPANY, Waltham, MA (US)

(72) Inventor: William E. Hoke, Wayland, MA (US)

(73) Assignee: Raytheon Company, Waltham, MA (US)

(21) Appl. No.: 13/733,640

(22) Filed: Jan. 3, 2013

(51) Int. Cl. H01L 29/20

(52) U.S. Cl. CPC H01L 29/2003
USPC 257/76; 438/478

(57) ABSTRACT

A semiconductor structure having: a first semiconductor layer; and an electric carrier generating layer disposed on the first semiconductor layer to generate electric carriers within the first semiconductor layer by polarization effects, the electric carrier generating layer having a predetermined conduction band and a predetermined valance band, the electric carrier generating layer having a concentration of non-carrier generating contaminants having an energy level, the difference in the energy level of the non-carrier type contaminants and the energy level of either the conduction band or the valence band being greater than 10 kT, where k is Boltzmann's constant and T is the temperature of the electric carrier generating semiconductor layer, the electric carrier generating semiconductor layer being doped with a dopant having an energy level, the difference in the energy level of the dopant and the energy level of either the conduction band or the valence band being greater than 10 kT, the dopant having a concentration equal to or greater than the concentration of the non-carrier generating contaminants.

### TECHNICAL FIELD

This disclosure relates generally to semiconductor structures and more particularly to semiconductor structures wherein mobile electric carriers are generated through polarization effects.

### BACKGROUND AND SUMMARY

As is known is the art, in solid state physics, a band gap, also called an energy gap or bandgap, is an energy range in a pure crystalline solid where no electronic states can exist. In graphs of the electronic band structure of such crystalline solids the band gap generally refers to the energy difference (in electron volts, eV) between the top of the valence band and the bottom of the conduction band is insulators and semiconductors. In many semiconductor devices, such as in transistor devices, dopants are incorporated into the crystal which create electronic states inside the bandgap. If the energy of the electronic state is within approximately kT of the conduction band, where k is Boltzmann's constant and T is the temperature of the semiconductor (kT near room temperature at 300K is 0.026 eV), electrons have enough thermal energy to enter the conduction band and be conducted in the presence of an electric field. Similarly if the dopant electronic state is within approximately kT in energy of the valence band, holes can enter the valence band and be conducted in the presence of an electric field. As the difference in energy between the electronic state and the conduction band or valence band increases greater than kT, fewer electronic carriers (i.e., electrons or holes) are created. If the dopant electronic state is more than approximately 10 kT in energy from either the conduction band or valence band, thermal energy is insufficient to create any significant number of electron or hole carriers. Instead electrons in the conduction band or holes in the valence band can fall into these lower energy levels and be trapped or captured. It should also be noted that in imperfect crystalline solids, defects can exist which also introduce electronic states into the band gap.

As is also known in the art, one type of semiconductor structure, such as a GaAs pseudomorphic High Electron Mobility Transistor (pHEMT), incorporates an extrinsically doped, such as with silicon dopant atoms, AlGaAs barrier layers to provide electrons (i.e., the carriers) to a pHEMT channel layer. The silicon energy level in an Al_{0.25}Ga_{0.75}As layer often used in pHEMTs is less than kT below the conduction band of AlGaAs so electronic carriers are efficiently created by silicon doping.

Another type of semiconductor structure, such as the GaN High Electron Mobility Transistor (HEMT), derives mobile carriers through piezoelectric (strain) and/or inherent spontaneous polarization effects. More particularly, polarization occurs when the weighted average center of the positive charge from the protons in the atoms' nuclei is not at the same point in space as the weighted average negative charge of the electrons bonded between the atoms. For example, at the AlGaN/GaN interface there are two types of polarization generated charge: one is independent of strain (spontaneous polarization) and one is dependent on strain (piezoelectric polarization). Spontaneous polarization occurs at the AlGaN/GaN interface due to differences in the AlGaN and GaN charge distributions in the absence of strain. Strain dependent polarization occurs at the AlGaN/GaN interface because the smaller lattice constant AlGaN layer is stretched on the GaN layer which slightly changes the bond angles in the AlGaN layer and consequently the polarization. Other materials can be used to generate polarization charge. For example, a structure having an AlₓIn₁₋ₓN layer, where 0<X≦1 (such as Al_{0.83}In_{0.17}N) instead of AlGaN interfacing with the GaN layer will create, by these polarization effects, carriers in the GaN. Further, it is known that silicon has been added to the AlGaN layer to provide carriers to the GaN; it being noted that silicon has an energy level close to kT (i.e., less than 10 kT lower than the conduction band of AlGaN) to efficiently create electronic carriers.

One example of a polarization semiconductor device structure is the GaN HEMT shown in FIG. 1. Here, a substrate, for example, silicon carbide (SiC), silicon (Si) or Sapphire, has a 200 Angstrom to 1000 Angstrom thick, nucleation layer (NL) of Aluminum Nitride (AlN) formed on it and a 1-3 micron thick III-V buffer layer of here for example GaN formed on the AlN layer. A 50-300 Angstrom thick barrier layer of undoped Aluminum Gallium Nitride (AlₓGa₁₋ₓN) is under tensile, elastic strain on the GaN buffer layer thereby causing piezoelectric charge to form in the top-most portion of the GaN layer. Also at the AlGaN/GaN interface, the difference in the spontaneous polarization of these two materials results is additional polarization effect produced charge in the top-most portion of the GaN layer. Consequently this structure can possess significant mobile carriers.

As important issue with polarization device structures such as the GaN HEMT device is device leakage currents. More particularly, in growing the AlGaN layer there are contaminants in the growth process such as oxygen which can provide unwanted electronic carriers because they have energy levels less than 10 kT from either the conduction band or the valance band of the AlGaN layer. These contaminants are referred to herein as carrier generating contaminants. Under high fields in the device structure, these unwanted carriers (derived from the contaminants) increase the leakage current of the device. These carrier generating contaminants such as oxygen have been observed in the AlGaN layer with concentrations in the 1-5×10¹⁷ atoms cm³ range. Also charge may be released by defects such as dislocations in the AlGaN layer produced during the growth process. Further, in the above layer structure (FIG. 1), a control electrode is used to control the flow of carriers in the AlₓGa₁₋ₓN and GaN layers. Under reverse bias conditions, the highest fields in the HEMT device exist in the AlₓGa₁₋ₓN barrier layer. Conductivity caused by the carrier generating contaminants or crystalline defects which have an energy level within 10 kT of the valence band or conduction band in this layer will result in device leakage resulting in degraded performance such as reduced efficiency and breakdown voltage. It should also be noted that during the formation of the AlₓGa₁₋ₓN barrier layer there may be contaminants having energy levels greater than 10 kT from the valance band or conduction band; however these contaminants are non-carrier generating contaminants and have concentrations less than 10¹⁷ atoms cm⁻³, i.e. a concentration less than the concentration of the carrier generating contaminants.

One approach suggested to solve this leakage problem is to form an insulator, such as SiN, between the gate electrode and AlGaN barrier layer thereby forming an IGFET (insulated gate field effect transistor) structure. This approach however may not always be desirable because: first, an additional and different material (i.e., the insulator) must now be deposited onto the AlₓGa₁₋ₓN surface of the GaN HEMT; this insulator material must not degrade or react with the AlₓGa₁₋ₓN surface at process temperatures; and unless the AlGaN layer is thinned, the gate electrode will be further away from the carriers thereby reducing the transconductance of the device.

The inventor has recognized that rather than adding an insulator layer to the structure of FIG. 1 for the purpose of reducing the aforementioned leakage problem, the inventor adds a compensation dopant during growth of the AlₓGa1₋ₓN barrier layer, such dopant having an energy level inside the bandgap of the AlₓGa1₋ₓN barrier layer and having a difference in energy from either the conduction band or the valence band, of the AlₓGa₁₋ₓN barrier layer greater than 10 kT, where k is Boltzmann's constant and T is the temperature of the AlₓGa₁₋ₓN barrier layer and having a concentration equal to or greater than the concentration of carrier generating contaminants in the AlₓGa₁₋ₓN barrier to trap the electronic charge from the carrier generating contaminants in the AlₓGa₁₋ₓN barrier layer.

The compensation doped Aluminum Gallium Nitride (AlₓGa₁₋ₓN) barrier layer is under tensile, elastic strain on the GaN buffer layer thereby again causing piezoelectric charge to form is the top-most portion of the GaN layer. Also at the AlGaN/GaN interface, the difference in the spontaneous polarization of these two materials again results in additional polarization charge in the top-most portion, of the GaN layer. Here, however, for the compensation doped AlₓGa₁₋ₓN barrier layer, unwanted electric carriers derived from the carrier generating contaminants in the AlₓGa₁₋ₓN barrier layer are trapped out by the compensation doping therein, resulting hi a much more resistive AlGaN layer and a device having reduced leakage current. The unwanted carriers derived from the carrier generating contaminants in the AlGaN barrier layer are now trapped by the compensation doping. More particularly, the trap atoms (i.e., the compensation dopant) added to the AlₓGa₁₋ₓN barrier layer capture the electronic charge derived from the carrier generating contaminants in the AlₓGa₁₋ₓN barrier layer, resulting in a much more resistive AlₓGa₁₋ₓN barrier layer with reduced leakage current. Consequently an IGFET-like structure is in effect obtained without growing an insulating layer on the AlGaN surface.

With such an arrangement, the resistivity of the compensation doped AlGaN layer is increased by trapping out or capturing unwanted electronic charge from carrier generating contaminants in the AlGaN barrier layer. With these unwanted electronic carriers eliminated, the device structure will have lower leakage entreats without requiring an insulating layer on the AlGaN surface. Further, the compensation doping in the AlGaN barrier layer does not significantly reduce the carrier concentration in the topmost portion of the GaN layer created by polarization effects.

In accordance with the present disclosure, a semiconductor structure is provided having a first semiconductor layer; and an electric carrier generating layer disposed on the first semiconductor layer to generate electric carriers within the first semiconductor layer by polarization effects. The electric carrier generating layer includes a predetermined conduction band and a predetermined valance band. The electric carrier generating layer has a concentration of non-carrier generating contaminants having an energy level, the difference in the energy level of the non-carrier type contaminants and the energy level of either the conduction band or the valence band being greater than 10 kT, where k is Boltzmann's constant and T is the temperature of the electric carrier generating semiconductor layer. The electric carrier generating semiconductor layer is doped with a predetermined dopant having a predetermined doping concentration, the dopant has an energy level the difference in energy of the energy level of the dopant and the energy level of either the conduction band or the valence band being greater than 10 kT.

In one embodiment, a semiconductor structure is provided having a first semiconductor layer and an electric carrier generating semiconductor layer disposed on the first semiconductor layer to generate electric carriers within the first semiconductor layer by polarization effects, the electric carrier generating layer having a predetermined conduction band and a predetermined valance band, the electric carrier generating layer having a concentration of non-carrier generating contaminants having an energy level, the difference in the energy level of the non-carrier generating contaminants and the energy level of either the conduction band or the valence band being greater than 10 kT, where k is Boltzmann's constant and T is the temperature of the electric carrier generating semiconductor layer, the electric carrier generating semiconductor layer being doped with a dopant having an energy level, the difference in the energy level of the dopant and the energy level of either the conduction band or the valence band being greater than 10 kT, the dopant having a concentration equal to or greater than the concentration of the non-carrier generating contaminants.

In one embodiment the concentration of the dopant is greater than the concentration of the non-carrier generating contaminants.

In one embodiment, the first semiconductor layer is a nitride.

In one embodiment the first semiconductor layer is GaN.

In one embodiment, the electric carrier generating semiconductor layer has a bandgap greater than the bandgap of the first semiconductor layer.

In one embodiment, the electric carrier generating semiconductor layer is a nitride.

In one embodiment the electric carrier generating layer is AlₓGa₁₋ₓN.

In one embodiment, the electric carrier generating layer is AlN.

In one embodiments the electric carrier generating layer is AlGaInN.

In one embodiment, the electric carrier generating layer is AlₓGa₁₋ₓN.

In one embodiment, the first semiconductor layer is a III-V layer.

In one embodiment, the first semiconductor layer is a GaN.

In one embodiment, the semiconductor structure includes electrodes, in contact with the compensation doped layer, for controlling a flow of the carriers through either the first semiconductor layer or the electric carrier generating semiconductor layer.

In one embodiment the external dopant is carbon, beryllium, chromium, vanadium, or iron.

In one embodiment, a method is provided for forming a semiconductor structure. The method includes: providing a first semiconductor layer; growing an electric carrier generating layer on the first semiconductor layer to generate electric carriers within the first semiconductor layer by polarization effects, the electric carrier generating layer having a predetermined conduction band and a predetermined valance band; and introducing to the electric carrier generating layer during the growing of the electric carrier generating layer a dopant having an energy level, the difference in the energy level of the dopant and the energy level of either the conduction band or the valence band being greater than 10 kT, where k is Boltzmann's constant and T is temperature of the electric carrier generating layer and having a concentration 5 to 20×10¹⁷ atoms cm⁻³.

The details of one or more embodiments of the disclosure are set forth in the accompanying drawings and the description below. Other features, objects, and advantages of the disclosure will be apparent from the description and drawings, and from the claims.

### DESCRIPTION OF DRAWINGS

FIG. 1 is a diagrammatical cross sectional sketch of a semiconductor structure suitable for use in a HEMT device according to the PRIOR ART;

FIG. 2 is a diagrammatical cross sectional sketch of a HEMT device according to the disclosure; and

FIG. 3 is a set of curves showing the effect of carbon doping in an AlGaN layer of the HEMT of FIG. 2, on leakage current.

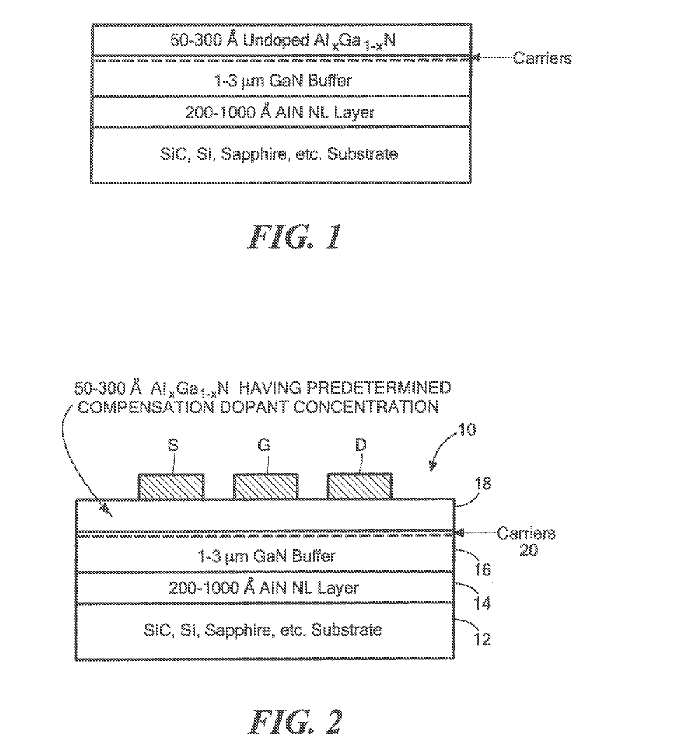

Like reference symbols in the various drawings indicate like elements.

### DETAILED DESCRIPTION

Referring now to FIG. 2, a HEMT device 10 is shown having a substrate 12, for example, silicon carbide (SiC), silicon (Si) or Sapphire, has a 200 Angstrom to 1000 Angstrom thick, nucleation layer (NL) 14 of Aluminum Nitride (AlN) formed on substrate 12 and a 1-3 micron thick III-V semiconductor buffer layer 16 of here, for example, GaN formed on the AlN layer 14. A 50-300 Angstrom thick layer 18 of here carbon-doped Aluminum Gallium Nitride (AlₓGa₁₋ₓN) barrier is under tensile, elastic strain on the GaN buffer layer 16 thereby causing piezoelectric polarization charge 20 to form in the top-most portion of the GaN layer 16. Also at the AlGaN/GaN interface, the difference in the spontaneous polarization of these two materials results in additional polarization charge 20 in the top-most portion of the GaN layer 16.

It should also be noted that during the formation of the AlₓGa₁₋ₓN barrier layer there may be contaminants having energy levels outside of 10 kT from the valance band or conduction band (i.e., non-carrier generating contaminants) having a concentrations of less than 10¹⁷ atoms cm⁻³, i.e. a concentration less than the concentration of the carrier generating contaminants in the AlₓGa₁₋ₓN barrier layer.

More particularly, the Aluminum Gallium Nitride (AlₓGa₁₋ₓN) layer 18 is an electric carrier generating layer disposed on the III-V layer 16 to generate electric carriers within the III-V layer 16 by polarization effects. The electric carrier generating layer 18 is doped during its growth process with a compensating dopant having an energy level which has a difference in energy from either the conduction band or valence band that is greater than 10 kT, where k is Boltzmann's constant and T is the electric carrier generating layer 18 temperature and which has a concentration equal to or greater than the concentration of the non-carrier contaminants, here, for example 5×10¹⁷ atoms cm⁻³. Thus, the compensation dopant captures the electronic charge derived from the carrier generating contaminants within the electric carrier generating layer 18 (i.e., carriers derived from carrier generating contaminants within the electric carrier generating layer 18). Here, for example the compensating dopant may be, for example, carbon, beryllium, chromium, vanadium, or iron. It should be understood that other materials may be used for the electric carrier generating layer 18, for example AlₓGa₁₋ₓN. Further, the electric carrier generating semiconductor layer 18 has a bandgap greater than the bandgap of the GaN semiconductor buffer layer 16.

The HEMT device structure includes source, S, drain, D, and Gate, G, electrodes, as shown in FIG. 2. The gate electrode controls the flow of the electric carriers 20 passing through either the GaN layer 16 or the electric carrier generating layer 18 or both layers, depending on the bias voltage, between the source, gate, and drain electrodes,

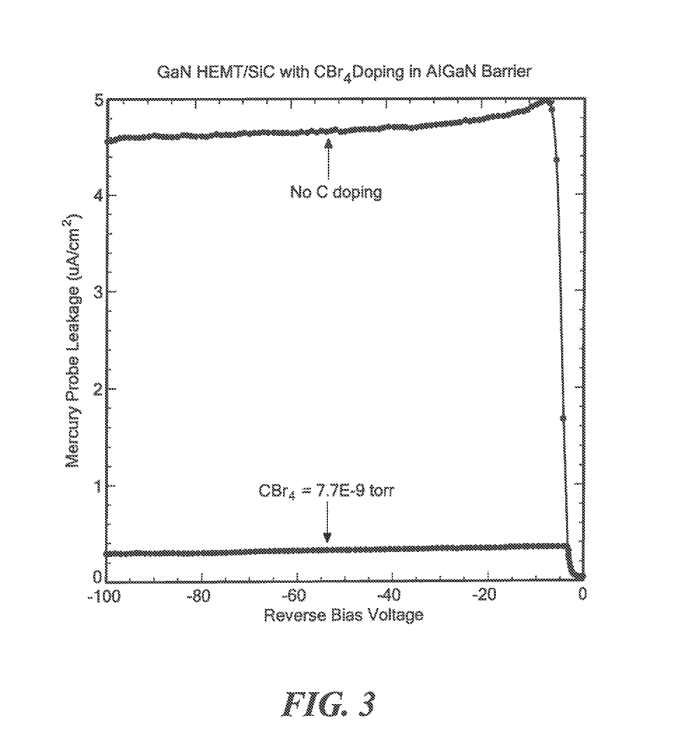

The structure 10 was tested by growing the same GaN HEMT structure with and without carbon doping in the AlGaN layer. Carbon tetrabromide, CBr₄, was used as the source of carbon doping. FIG. 3 shows the reverse bias mercury probe Schottky barrier leakage current results for GaN HEMT wafers with and without carbon doping in the AlGaN layer. In the mercury probe measurements, mercury is in contact with the AlGaN layer 18 surface and provides the gate electrode, G, as well as the contact electrode so that the device structure can be biased. From FIG. 3, the wafer with carbon doping exhibits a leakage at −100 volts reverse bias that is more than an order of magnitude smaller than without the compensation doping. Importantly, the presence of carbon doping had little effect on the sheet resistance of the wafer and consequently had little effect on the polarization charge in the topmost portion of the GaN layer which provides the electric carriers for the device current of the structure. The wafer with no carbon doping had a sheet resistance of 422 ohm/sq for a 24.4% AlGaN barrier layer 18. The sheet resistance of the carbon doped wafer had a sheet resistance of 418 ohm/sq for a 25.4% AlGaN barrier layer 18. The nearly identical sheet resistance indicates that the carbon compensation doping in the AlGaN layer is not compensating and thus reducing the device channel charge in the GaN layer which would have increased the sheet resistance. Carrier generating contaminants such as oxygen having concentrations in the 1-5×10¹⁷ atoms cm⁻³ range have been observed in layer 18 so a higher concentration (5 to 20×10¹⁷ atoms cm⁻³) of carbon was used to trap out the electronic charge caused by the oxygen contaminants.

A number of embodiments of the disclosure have been described. Nevertheless, it will be understood that various modifications may be made without departing from the spirit and scope of the disclosure. For example, the electric carrier generating layer 18 may be Al_{y}Ga_{1-y})ₓIn₁₋ₓN, AlₓIn₁₋ₓN, or AlN for example. Accordingly, other embodiments are within the scope of the following claims,.

What is claimed is:

1. A semiconductor structure, comprising:
a first semiconductor layer; and
an electric carrier generating layer disposed on the first semiconductor layer to generate electric carriers within the first semiconductor layer by polarization effects, the electric carrier generating layer having a predetermined conduction band and a predetermined valance band, the electric carrier generating layer having a concentration of non-carrier generating contaminants having an energy level, the difference in the energy level of the non-carrier type contaminants and the energy level of either the conduction band or the valence band being greater than 10 kT, where k is Boltzmann's constant and T is the temperature of the electric carrier generating semiconductor layer, the electric carrier generating semiconductor layer being doped with a predetermined dopant having a predetermined doping concentration, the dopant having an energy level the difference in energy of the energy level of the dopant and the energy level of either the conduction band or the valence band being greater than 10 kT.

2. The semiconductor structure recited in claim 1 wherein the electric carrier generating layer is AlₓGa₁₋ₓN, AlₓIn₁₋ₓN, or (Al_{y}Ga_{1-y})ₓIn₁₋ₓN with 0<X≦1 and 0<Y≦1.

3. The semiconductor structure recited in claim 2 wherein the first semiconductor layer is a nitride.

4. The semiconductor structure recited in claim 2 wherein the first semiconductor layer is a III-V layer.

5. The semiconductor structure recited in claim 2 wherein the III-V layer is GaN.

6. The semiconductor structure recited in claim 1 including electrodes in contact with the electric carrier generating layer for controlling a flow of the carriers through the first semiconductor layer.

7. The semiconductor structure recited in claim 1 wherein the dopant is carbon, beryllium, chromium, vanadium, or iron.

8. The semiconductor structure recited in claim 2 wherein the dopant is carbon, beryllium, chromium, vanadium, or iron.

9. The semiconductor structure recited in claim 3 wherein the dopant is carbon, beryllium, chromium, vanadium or iron.

10. The semiconductor structure recited in claim 4 wherein the dopant is carbon, beryllium, chromium, vanadium or iron.

11. The semiconductor structure recited in claim 1 wherein the dopant captures charge carriers arising from contaminants or crystalline defects within the electric carrier generating layer.

12. The semiconductor structure recited in claim 2 wherein the dopant captures charge carriers arising from contaminants or crystalline defects within the electric carrier generating layer.

13. The semiconductor structure recited in claim 3 wherein the dopant captures charge carriers arising from contaminants or crystalline defects within the electric carrier generating layer.

14. A method for forming a semiconductor structure, comprising:
providing a first semiconductor layer;
growing an electric carrier generating layer on the first semiconductor layer to generate electric carriers within the first semiconductor layer by polarization effects, the electric carrier generating layer having a predetermined conduction band and a predetermined valance band,
introducing to the electric carrier generating layer during the growing of the electric carrier generating layer a dopant having an energy level, the difference in the energy level of the dopant and the energy level of either the conduction band or the valence band being greater than 10 kT, where k is Boltzmann's constant and T is temperature of the electric carrier generating layer and having a predetermined concentration.

15. A method for forming a semiconductor structure, comprising:
providing a first semiconductor layer;
providing a source of a predetermined dopant having an energy level;
growing an electric carrier generating layer on the first semiconductor layer to generate electric carriers within the first semiconductor layer by polarization effects, the electric carrier generating layer having a predetermined conduction band and a predetermined valance band including introducing to the electric carrier generating layer during the growing of the electric carrier generating layer the predetermined dopant, the difference in the energy level of the dopant and the energy level of either the conduction band or the valence band being greater than 10 kT, where k is Boltzmann's constant and T is temperature of the electric carrier generating layer.

16. The method recited in claim 15 wherein the growing includes providing the electric carrier generating layer with a predetermined concentration of the dopant.

17. The method recited in claim 16 wherein the concentration is at least 5 to 20×10¹⁷ atoms cm⁻³.

18. A semiconductor structure, comprising:
a first semiconductor layer; and
an electric carrier generating layer disposed on the first semiconductor layer to generate electric carriers within the first semiconductor layer by polarization effects, the electric carrier generating layer having a predetermined conduction band and a predetermined valance band, the electric carrier generating layer having a concentration of non-carrier generating contaminants having an energy level, the difference in the energy level of the non-carrier type contaminants and the energy level of either the conduction band or the valence band being greater than 10 kT, where k is Boltzmann's constant and T is the temperature of the electric carrier generating semiconductor layer, the electric carrier generating semiconductor layer being doped with a dopant having an energy level, the difference in energy of the energy level of the dopant and the energy level of either the conduction band or the valence band greater than 10 kT, the dopant having a concentration equal to or greater than the concentration of the non-carrier generating contaminants.

19. The method recited in claim 14 wherein the dopant concentration is 5 to 20×10¹⁷ atoms cm⁻³.
